(19) United States
(12) Patent Application Publication
(10) Pub. No.: US 2015/0228602 A1
(43) Pub. Date: Aug. 13, 2015

(54) SEMICONDCUTOR CHIP AND SEMIONDUCOT MODULE

(71) Applicant: Sony Corporation, Tokyo (JP)

(72) Inventor: Masahiro Sato, Tokyo (JP)

(21) Appl. No.: 14/576,720

(22) Filed: Dec. 19, 2014

(30) Foreign Application Priority Data
Feb. 12, 2014 (JP) 2014-024207

(51) Int. Cl. H01L 23/00; H01L 23/528; H01L 23/50; H01L 23/522

(52) U.S. Cl. CPC H01L 24/14; H01L 23/5226; H01L 23/528; H01L 23/50

(57) ABSTRACT

A semiconductor chip includes a signal terminal disposed on a chip substrate; a ground terminal disposed on the chip substrate; a signal cell disposed on the chip substrate; a ground cell disposed on the chip substrate; a signal line connecting the signal cell and the signal terminal; and a ground line wired along the signal line to connect the ground cell and the ground terminal. A semiconductor module includes the semiconductor chip; and a semiconductor package having a ground pad connected to the ground terminal, and a power source pad connected to the power source terminal.

### CROSS REFERENCE TO RELATED APPLICATIONS

This application claims the benefit of Japanese Priority Patent Application JP 2014-024207 filed Feb. 12, 2014, the entire contents of which are incorporated herein by reference.

### BACKGROUND

The present disclosure relates to a semiconductor chip and a semiconductor module. More particularly, the present disclosure relates to a semiconductor chip and a semiconductor module where bumps are disposed.

In the related art, a variety of mounting technologies such as a wire bonding method and a flip-chip bonding method are used to mount a semiconductor chip on a package substrate. The wire bonding method is to connect electrodes disposed on a semiconductor chip and a package substrate using conductive wires. In the meantime, the flip-chip bonding method is to connect a semiconductor chip to a package substrate by protruded terminals, which are disposed on the semiconductor chip in a two dimensional lattice array and are called as bumps, using no wires. The flip-chip bonding method is characterized by a small mounting area and good electrical properties as compared to the wire bonding method, and is often used when a compact size and good electrical properties have a priority.

For example, Japanese Patent Application Laid-open No. 2003-264256 proposes a semiconductor chip used for the flip-chip bonding method where an input output cell is disposed near a center axis of the semiconductor chip and a bump is connected to the input output cell. The semiconductor chip includes a power source bump connected via a power source line, a ground bump connected via a ground line and a signal bump connected via a signal line. The ground bump is disposed near the center axis, and the signal bump is disposed at a distance from the center axis.

### SUMMARY

In the above-described related art, as the signal bump is disposed at a distance from the ground bump, inductance of a loop coil composed of the signal line and the ground line connected to these bumps may be increased, resulting in degraded signal properties. In addition, as the number of the power source bump and the ground bump is decreased, the power source properties are degraded. As a result, the signal properties are undesirably significantly degraded.

In view of the circumstances as described above, there is a need for providing a semiconductor chip having improved signal properties.

According to an embodiment of the present disclosure, there is provided a semiconductor chip, including: a signal terminal disposed on a chip substrate; a ground terminal disposed on the chip substrate; a signal cell disposed on the chip substrate; a ground cell disposed on the chip substrate; a signal line connecting the signal cell and the signal terminal; a ground line wired along the signal line to connect the ground cell and the ground terminal. This allows the ground line wired along the signal line to connect the ground cell and the ground terminal.

According to an embodiment of the present disclosure, the semiconductor chip may further include a power source terminal disposed on the chip substrate; a power source cell disposed on the chip substrate; and a power source line arranged along the ground line to connect the power source terminal and the power source cell, the signal terminal may be disposed at an outer periphery of the chip substrate nearer than the ground terminal, and the ground terminal may be disposed at an outer periphery of the chip substrate nearer than the power source terminal. In this manner, the signal terminal can be disposed at the outer periphery of the chip substrate nearer than the ground terminal, and the ground terminal can be disposed at the outer periphery of the chip substrate nearer than the power source terminal.

According to an embodiment of the present disclosure, a plurality of the ground cells may be disposed on the chip substrate, and the ground terminal may be commonly connected to the respective ground cell. In this manner, the ground terminal can be connected commonly to the respective ground cells.

According to another embodiment of the present disclosure, there is provided a semiconductor module, including: a semiconductor chip having a signal terminal disposed on a chip substrate, a ground terminal disposed on the chip substrate, a signal cell disposed on the chip substrate, a ground cell disposed on the chip substrate, a signal line connecting the signal cell and the signal terminal, and a ground line wired along the signal line and connecting the ground cell and the ground terminal; and a semiconductor package having a ground pad connected to the ground terminal, and a power source pad connected to the power source terminal. In this manner, the ground line wired along the signal line can connect the ground cell and the ground terminal.

According to another embodiment of the present disclosure, the semiconductor chip may further include a power source terminal disposed on the chip substrate; the semiconductor package may include a power source pad connected to the power source terminal, a signal line wiring layer to which a signal line connected to the signal pad is wired, a ground line wiring layer to which a ground line connected to the ground pad is wired, and a power source wiring layer to which a power source line connected to the power source pad is wired; and the ground line wiring layer is disposed between the signal line wiring layer and the power source line wiring layer. In this manner, the ground line wiring layer can be disposed between the signal line wiring layer and the power source line wiring layer.

According to another embodiment of the present disclosure, the semiconductor package may further include a first via connecting the signal line wiring layer and the ground line wiring layer, and a second via connecting the signal line wiring layer and the power source wiring layer through the ground line wiring layer. In this manner, the signal line wiring layer and the ground line wiring layer can be connected by the first via, and the signal line wiring layer and the power source line wiring layer can be connected by the second via.

According to another embodiment of the present disclosure, the semiconductor package may further include an electrode layer on which a signal electrode connected to the signal pad, a ground electrode connected to the ground pad and a power source electrode connected to the power source pad are disposed; the signal electrode is disposed at an outer periphery of the electrode layer nearer than the ground electrode; and the ground electrode is disposed at an outer periphery of the electrode layer nearer than the power source electrode. In this manner, the signal electrode can be disposed at the outer periphery of the electrode layer nearer than the ground electrode, and the ground electrode can be disposed at the outer periphery of the electrode layer nearer than the power source electrode.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is an illustrative sectional diagram of a semiconductor module according to a first embodiment;

FIG. 2 is an illustrative plan diagram of a chip substrate according to the first embodiment;

FIG. 3 is an illustrative enlarged diagram of the chip substrate according to the first embodiment;

FIG. 4 is an illustrative enlarged diagram of the chip substrate having decreased power source bumps according to the first embodiment;

FIG. 5 is an illustrative enlarged diagram of the chip substrate where a position of an IO cell array is changed according to the first embodiment;

FIG. 6 is an illustrative top diagram of a package substrate according to the first embodiment;

FIG. 7 is an illustrative sectional diagram of a semiconductor package according to the first embodiment;

FIG. 8 is an illustrative perspective view of a semiconductor package according to the first embodiment; and

FIG. 9 is an illustrative plan view of an electrode layer according to the first embodiment.

### DETAILED DESCRIPTION OF EMBODIMENTS

Hereinafter, an embodiment of the present disclosure will be described with reference to the drawings.

The embodiments of the present disclosure will be described in the following order.

1. First Embodiment (a ground conductor is wired along a signal line)

### 1. First Embodiment

### Illustrative Configuration of Semiconductor Module

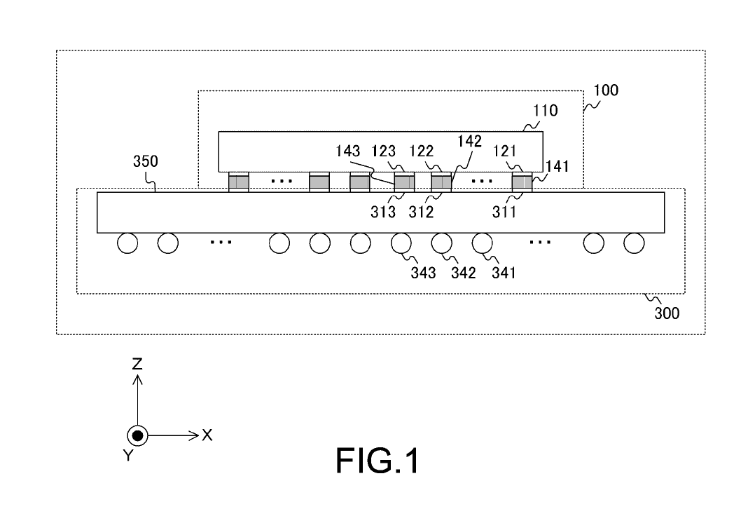

FIG. 1 is an illustrative sectional diagram of a semiconductor module according to a first embodiment. The semiconductor module includes a semiconductor chip 100 and a semiconductor package 300.

The semiconductor chip 100 includes a chip substrate 110, a plurality of bump pads and bumps disposed on the respective bump pads. On the surface of the chip substrate 100, as the bump pads, a signal pad 121 to which a signal line is connected, a ground pad 122 to which a ground line is connected and a power source pad 123 to which a power source line is connected are disposed. As the bumps, a signal bump 141 connected to the signal pad 121 via the signal line, a ground bump 142 connected to the ground pad 122 via the ground line and a power source bump 143 connected to the power source pad 123 via the power source line are disposed. Note that the signal bump 141, the ground bump 142 and the power source bump 143 are illustrative of the signal terminal, the ground terminal and the power source terminal described in the claims.

The semiconductor package 300 includes a package substrate 350, a plurality of bump pads and a plurality of ball electrodes. One surface of the semiconductor package 350 is connected to the semiconductor chip 100 and is referred to as an “upper surface” and the other surface is referred to as a “lower surface”. On the upper surface of the package substrate 350, as the bump pads, a signal pad 311 connected to the signal bump 141, a ground pad 312 connected to the ground bump 142 and a power source pad 313 connected to the power source bump 143 are disposed.

On the other hand, on the lower surface of the package substrate 350, as the ball electrodes, a power source electrode 343, a ground electrode 342 and a signal electrode 341 are disposed. The power source electrode 343 is the ball electrode connected to the power source pad 313 via the power source line. The ground electrode 342 is the ball electrode connected to the ground pad 312 via the ground line. The signal electrode 341 is the ball electrode connected to the signal pad 311 via the signal line.

When the above-described semiconductor chip 100 is mounted on the semiconductor package 300, the surface of the semiconductor chip 100 where the bumps are disposed is pressed to the semiconductor package 300. Then, a pressure treatment and a heating treatment allows the bumps of the semiconductor chip 100 to be melted to connect to the bump pads of the semiconductor package 300. In this manner, a method of mounting the semiconductor chip on the semiconductor package via the bumps is called as a flip-chip bonding method. The lower surface of the semiconductor package 300 is connected to a print substrate by a reflow method or the like.

### Illustrative Configuration of Chip Substrate

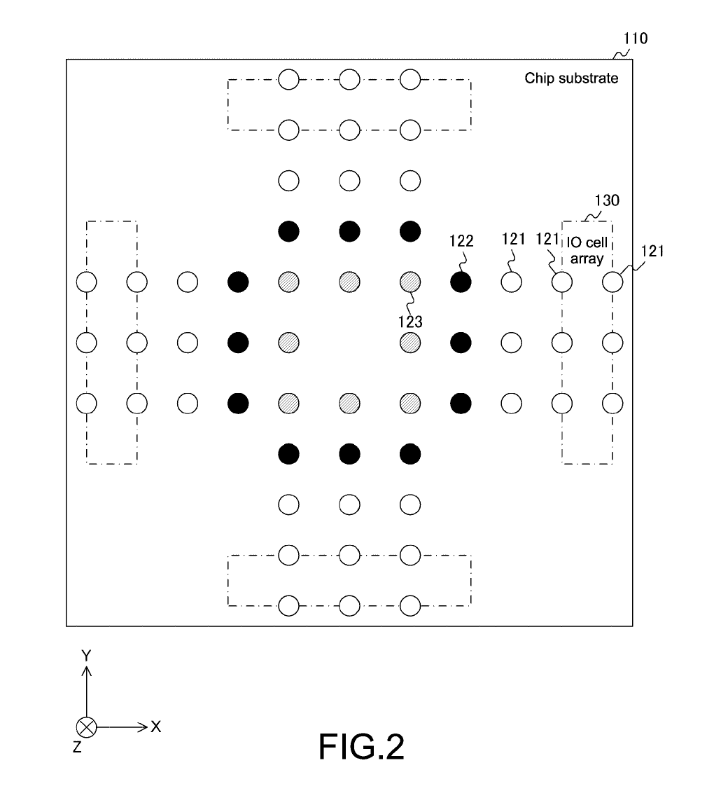

FIG. 2 is an illustrative plan diagram of a chip substrate 110 according to the first embodiment. The chip substrate 110 includes a plurality of signal pads 121, a plurality of ground pads 122, a plurality of power source pads 123 and IO (Input Output) cell arrays 130. In FIG. 2, hatched circles represent the light source pads 123, the black solid circle represent the ground pads 122 and white circles represent the signal pads 121. These signal pads 121, the ground pads 122 and the light source pads 123 are arrayed in a two dimensional lattice array, for example. Although signal lines, power source lines and ground lines are wired on the chip substrate 110, these are omitted as a matter of convenience.

A plurality of IO cells are arrayed in the IO cell arrays 130 along an outer periphery of the chip substrate. The respective signal pads 121 are disposed at the outer periphery of the chip substrate 110 nearer than the ground pads 122 and the power source pads 123. The ground pads 122 are disposed at the outer periphery of the chip substrate 110 nearer than the power source pads 123. In other words, the power source pads 123, the ground pads 122 and the signal pads 121 are disposed from a center to the outer periphery of the chip substrate 110 in this order.

A part of the signal pads 121 may be disposed above the IO cell array 130. In FIG. 2, three columns of the signal pads 121 are disposed along the outer periphery, the two columns of them near the outer periphery are disposed above the IO cell array 130.

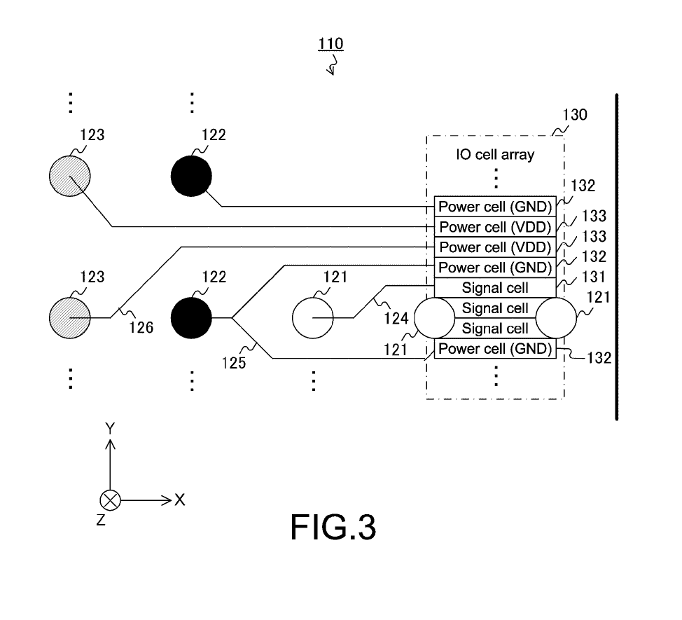

FIG. 3 is an illustrative enlarged diagram of the chip substrate 110 according to the first embodiment. A thick line in a right side represents the outer periphery of the chip substrate 110. Signal cells 131, power cells 132 and 133 are arrayed in the IO cell array 130 along the outer periphery of the chip substrate 110. In addition, the signal pads 121, the ground pads 122 and the power source pads 123 are disposed to which the signal line 124, the ground lines 125 and the power source lines 126 are wired.

The signal cells 131 are the IO cells for inputting and outputting signals to/from internal circuits of the semiconductor chip 100. The signal cells 131 are corresponded to the signal pads 121 and are connected to the corresponded signal pads 121 via the signal line 124.

As described above, as the signal pads 121 are disposed at the outer periphery of the chip substrate 110 nearer than the ground pads 122 and the power source pads 123, the ground lines 125 and the power source lines 126 less block pulling-out wiring of the signal line 124. Accordingly, the signal line 124 are easily wired and the number of signals is easily increased.

The power cells 132 are the IO cells for feeding a ground potential to the circuits within the semiconductor chip 100. The power cells 132 are corresponded to the ground pads 122 and are connected to the corresponded ground pads 122 via the ground lines 125. The ground lines 125 are wired along the signal line 124. Note that the power cells 132 are illustrative of the ground cells described in the claims.

Here, the signal pads 121 and the ground pads 122 are desirably positioned adjacent in the two dimensional lattice pad array. In addition, the signal cells 131 and the power cells 132 are desirably positioned adjacent in the IO cell array 130.

In this manner, the ground lines 125 are wired along the signal line 124, the ground pads 122 are disposed adjacent to the signal pads 121, and the power cells 132 are disposed adjacent to the signal cells 131, thereby decreasing inductance components of the signals. This is because a loop coil composed of a signal path between the signal pad 121 and the signal cell 131 and a return path between the ground pad 122 and the power cell 132 occupies a relatively small area. The smaller the area of the loop coil is, the smaller self-inductance L is. Inductance components (−L·dI/dt) corresponding to the self-inductance get small. Here, the dI/dt represents the time rate of change of current. As the inductance components get small, power source quality and high response get better.

In addition, at least one or more of the ground pads 122 are corresponded to two power cells 132 and one ground pad 122 is commonly connected to the power cells 132. The corresponding two power cells 132 are arrayed sandwiching the signal cells 131 in the IO cell array 130.

In this manner, one ground pad 122 is connected to a plurality of power cells 132, thereby decreasing the bump number per IO cell.

The power cells 133 are the IO cells for feeding power source potentials higher than the ground potential to the circuit within the semiconductor chip 100. The power cells 133 are corresponded to the power source pads 123 and are connected to the corresponded power source pads 123 via the power source lines 126. The power source lines 126 are wired along the ground lines 125. Note that the power cells 133 are illustrative of the power source cells described in the claims.

Here, the ground pads 122 and the power source pads 123 are desirably positioned adjacent in the two dimensional lattice pad array. In addition, the power cells 132 and the power cells 133 are desirably positioned adjacent in the IO cell array 130.

In this manner, the power source lines 126 are wired along the ground lines 125, the power source pads 123 are disposed adjacent to the ground pads 122, and the power cells 133 are disposed adjacent to the power cells 132, thereby decreasing power source impedance and radiative noises.

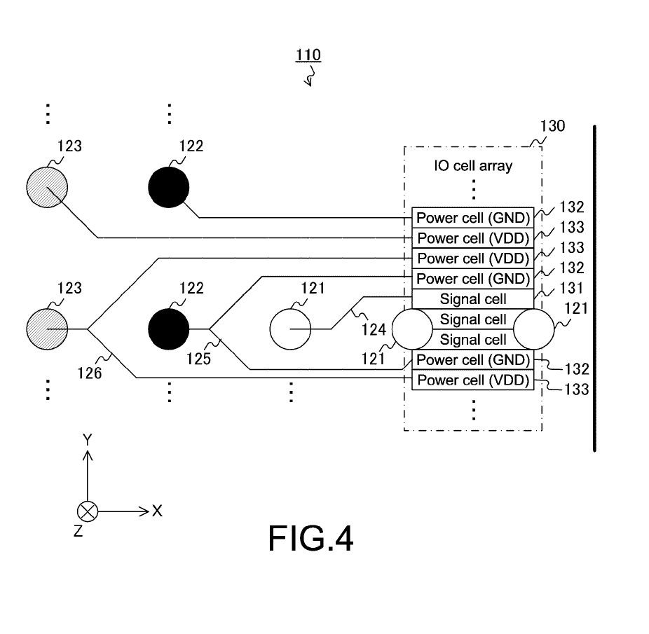

As shown in FIG. 4, at least one or more of the ground pads 123 may be corresponded to two power cells 133 and the ground pads 123 and connected to the power cells 133. In this case, the corresponding two power cells 133 are arrayed sandwiching the signal cells 131 and the power cells 132 in the IO cell array 130.

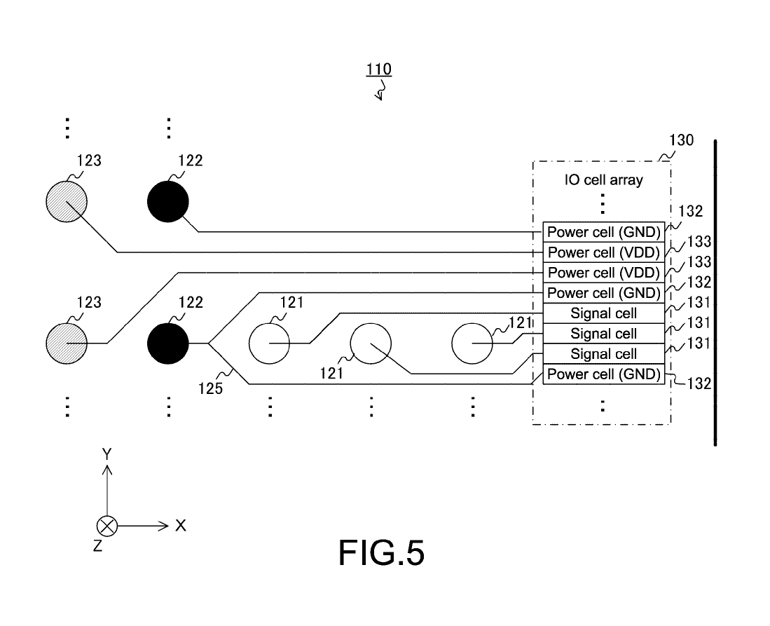

In the chip substrate 110, the two columns of the signal pads 121 are disposed above the IO cell array 130. As shown in FIG. 5, the IO cell array 130 may be taken away from the two columns of the signal pads 121 and may be disposed near the outer periphery of the chip substrate 110.

### Illustrative Configuration of Package Substrate

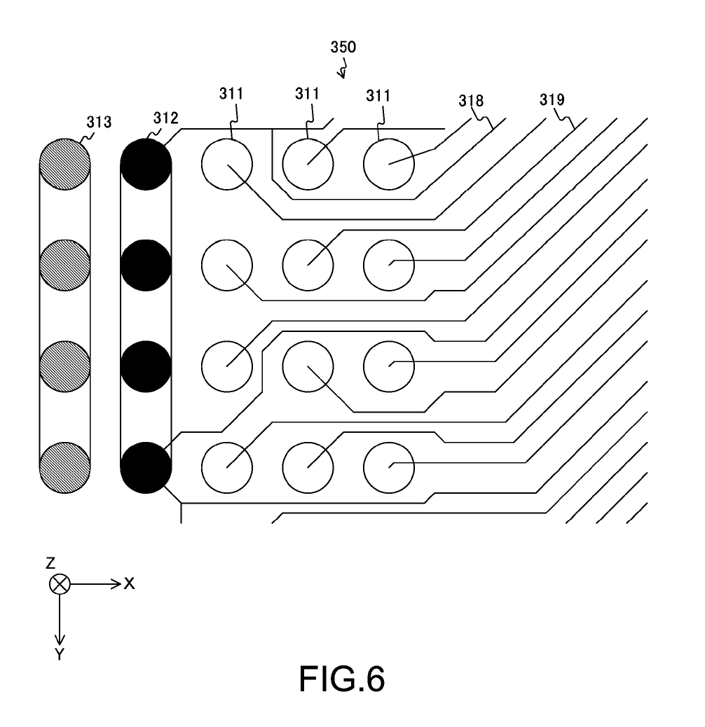

FIG. 6 is an illustrative top diagram of a package substrate 350 according to the first embodiment. On the upper surface of the package substrate 350, the signal pads 311, the ground pads 312 and the power source pads 313 are disposed corresponding to the positions of the bumps at the semiconductor chip 100. The ground lines 318 connected to the ground pads 312 and the signal lines 319 connected to the signal pads 311 are wired.?

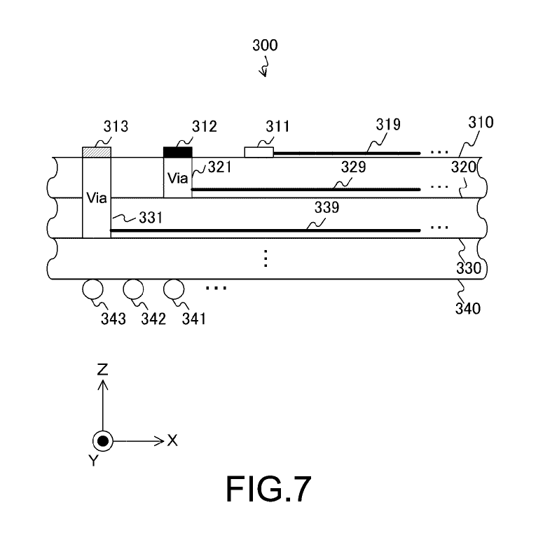

FIG. 7 is an illustrative sectional diagram of a semiconductor package 300 according to the first embodiment. The package substrate 350 includes a signal line wiring layer 310, a ground line wiring layer 320, a power source line wiring layer 330 and an electrode layer 340.

One of surfaces of the signal line wiring layer 310 forms an upper surface of the semiconductor package 300. On the upper surface, the signal pad 311, the ground pad 312 and the power source pad 313 are disposed and the signal line 319 is wired.

The ground line wiring layer 320 is disposed between the signal line wiring layer 310 and the power source line wiring layer 330. A ground line 329 is wired on the ground line wiring layer 320. The ground line wiring layer 320 is connected to the signal line wiring layer 310 by a via 321. The via 321 is disposed directly under the ground pad 312 to connect the ground line wiring layer 320 to the ground line 329. Note that the via 331 is illustrative of the second via described in the claims.

In this manner, when the ground line wiring layer 320 is disposed between the signal line wiring layer 310 and the power source line wiring layer 330, an electromagnetic wave is radiated from one of a power source line 339 and a signal line 319 and can decrease radiative noises generated in the other. This is because the ground line 329 disposed between the power source line 339 and the signal line 319 functions as a shield for inhibiting the electromagnetic wave.

One of surfaces of the electrode layer 340 forms a lower surface of the semiconductor package 300. On the lower surface, ball electrodes of the signal electrode 341, the ground electrode 342 and the power source electrode 343 are disposed. The ball electrodes are connected to the corresponding bump pads by the signal line, the ground line and the power source line via the power source line wiring layer 330 and the ground line wiring layer 320.

As shown in FIG. 7, the signal line wiring layer 310 is connected to the ground line wiring layer 320 and the power source line wiring layer 330, thereby shortening a path from the power source pad 313 and the ground pad 312 to the corresponding ball electrode. In this manner, the power source impedance can be decreased.

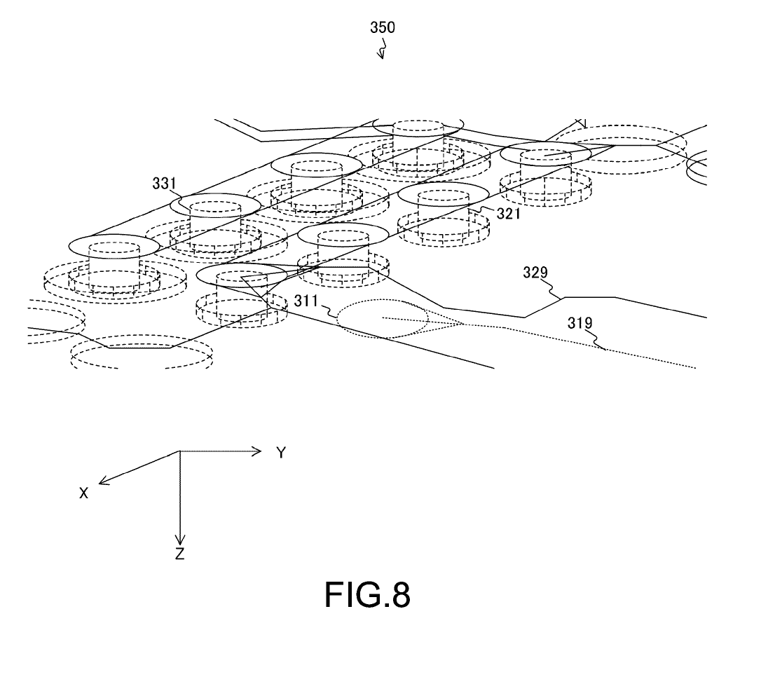

FIG. 8 is an illustrative perspective view of a semiconductor package substrate 350 according to the first embodiment. In FIG. 8, the ground line wiring layer 320 on which the ground line 329 is wired is represented by a solid line. The vias 321 and 331 and the signal line wiring layer 310 on which the signal line 319 is wired are represented by a dotted line. As shown in FIG. 8, these layers are connected by the vias 321.

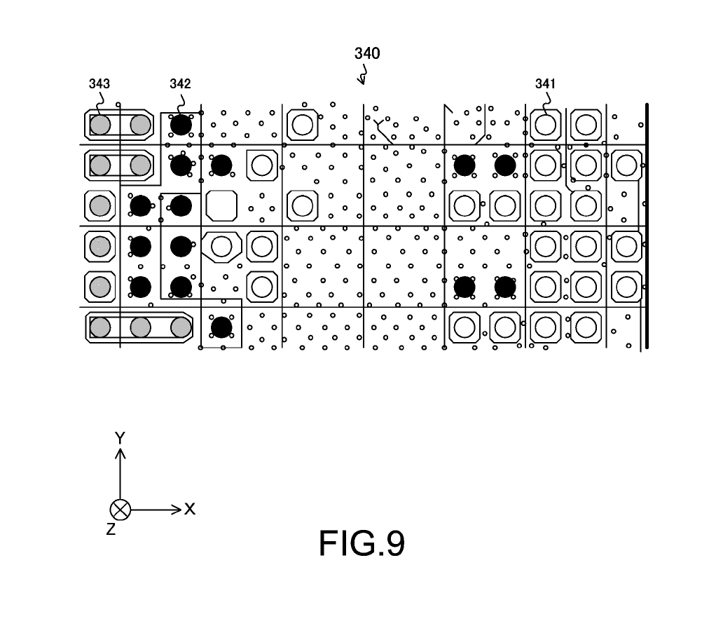

FIG. 9 is an illustrative plan view of the electrode layer 340 according to the first embodiment. A thick line in a right side represents an outer periphery of the electrode layer 340. In FIG. 9, hatched circles represent the power source electrodes 343, the black solid circles represent the ground electrodes 342 and white circles represent the signal electrodes 341. As shown in FIG. 9, these ball electrodes are arrayed in a two dimensional lattice array on the electrode layer 340. The semiconductor package having a plurality of ball electrodes arrayed in the two dimensional lattice array is called as a BGA (Ball Grid Array) package.

On the electrode layer 340, the respective signal electrodes 341 are disposed at the outer periphery of the electrode layer 340 nearer than the ground electrodes 342 and the power source electrodes 343. The ground electrodes 342 are disposed at the outer periphery of the electrode layer 340 nearer than the power source electrodes 343. In other words, the power source electrodes 343, the ground electrodes 342 and the signal electrodes 341 are disposed from a center to the outer periphery of the electrode layer 340 in this order.

Here, the ground electrodes 342 and the power source electrodes 343 are desirably positioned adjacent in the two dimensional lattice electrode array. In this manner, the power source impedance can be decreased.

As described above, according to the first embodiment of the present disclosure, as the ground lines connecting the ground cells and the ground terminals are wired along the signal lines, the inductance components of the signals can be decreased. In this manner, the signal quality can be improved.

The above-described embodiments are illustrative of the present disclosure and the matters in claims and the matters in the embodiments, especially the matters having the same designation as those in the claims, and have a correspondence relationship. The present disclosure is not limited to the above-described embodiments, and variations and modifications may be made without departing from the scope of the present disclosure.

The advantages described herein are not limited and any advantages provided by the present disclosure can be included.

The present disclosure may have the following configurations.

(1) A semiconductor chip, including:
a signal terminal disposed on a chip substrate;
a ground terminal disposed on the chip substrate;
a signal cell disposed on the chip substrate;
a ground cell disposed on the chip substrate;
a signal line connecting the signal cell and the signal terminal; and
a ground line wired along the signal line to connect the ground cell and the ground terminal.

(2) The semiconductor chip according to (1) above, further including:
a power source terminal disposed on the chip substrate;
a power source cell disposed on the chip substrate; and
a power source line arranged along the ground line to connect the power source terminal and the power source cell, in which
the signal terminal is disposed at an outer periphery of the chip substrate nearer than the ground terminal, and
the ground terminal is disposed at an outer periphery of the chip substrate nearer than the power source terminal.

(3) The semiconductor chip according to (1) or (2) above, in which
a plurality of the ground cells are disposed on the chip substrate, and the ground terminal is commonly connected to the respective ground cell.

(4) A semiconductor module, including:
a semiconductor chip having a signal terminal disposed on a chip substrate, a ground terminal disposed on the chip substrate, a signal cell disposed on the chip substrate, a ground cell disposed on the chip substrate, a signal line connecting the signal cell and the signal terminal, and a ground line wired along the signal line and connecting the ground cell and the ground terminal; and
a semiconductor package having a ground pad connected to the ground terminal, and a power source pad connected to the power source terminal.

(5) The semiconductor module according to (4) above, in which
the semiconductor chip further includes a power source terminal disposed on the chip substrate; and
the semiconductor package includes
a power source pad connected to the power source terminal,
a signal line wiring layer to which a signal line connected to the signal pad is wired,
a ground line wiring layer to which a ground line connected to the ground pad is wired, and
a power source wiring layer to which a power source line connected to the power source pad is wired; and
the ground line wiring layer is disposed between the signal line wiring layer and the power source line wiring layer.

(6) The semiconductor module according to (5) above, in which
the semiconductor package further includes
a first via connecting the signal line wiring layer and the ground line wiring layer, and
a second via connecting the signal line wiring layer and the power source wiring layer through the ground line wiring layer.

(7) The semiconductor module according to (5) or (6) above, in which
the semiconductor package further includes an electrode layer on which a signal electrode connected to the signal pad, a ground electrode connected to the ground pad and a power source electrode connected to the power source pad are disposed;
the signal electrode is disposed at an outer periphery of the electrode layer nearer than the ground electrode; and
the ground electrode is disposed at an outer periphery of the electrode layer nearer than the power source electrode.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor chip, comprising:
a signal terminal disposed on a chip substrate;
a ground terminal disposed on the chip substrate;
a signal cell disposed on the chip substrate;
a ground cell disposed on the chip substrate;
a signal line connecting the signal cell and the signal terminal; and
a ground line wired along the signal line to connect the ground cell and the ground terminal.

2. The semiconductor chip according to claim 1, further comprising:
a power source terminal disposed on the chip substrate;
a power source cell disposed on the chip substrate; and
a power source line arranged along the ground line to connect the power source terminal and the power source cell, wherein
the signal terminal is disposed at an outer periphery of the chip substrate nearer than the ground terminal, and
the ground terminal is disposed at an outer periphery of the chip substrate nearer than the power source terminal.

3. The semiconductor chip according to claim 1, wherein
a plurality of the ground cells are disposed on the chip substrate, and the ground terminal is commonly connected to the respective ground cell.

4. A semiconductor module, comprising:
a semiconductor chip having a signal terminal disposed on a chip substrate, a ground terminal disposed on the chip substrate, a signal cell disposed on the chip substrate, a ground cell disposed on the chip substrate, a signal line connecting the signal cell and the signal terminal, and a ground line wired along the signal line and connecting the ground cell and the ground terminal; and
a semiconductor package having a ground pad connected to the ground terminal, and a power source pad connected to the power source terminal.

5. The semiconductor module according to claim 4, wherein
the semiconductor chip further includes a power source terminal disposed on the chip substrate; and
the semiconductor package includes
a power source pad connected to the power source terminal,
a signal line wiring layer to which a signal line connected to the signal pad is wired,
a ground line wiring layer to which a ground line connected to the ground pad is wired, and
a power source wiring layer to which a power source line connected to the power source pad is wired; and
the ground line wiring layer is disposed between the signal line wiring layer and the power source line wiring layer.

6. The semiconductor module according to claim 5, wherein
the semiconductor package further includes
a first via connecting the signal line wiring layer and the ground line wiring layer, and
a second via connecting the signal line wiring layer and the power source wiring layer through the ground line wiring layer.

7. The semiconductor module according to claim 5, wherein
the semiconductor package further includes an electrode layer on which a signal electrode connected to the signal pad, a ground electrode connected to the ground pad and a power source electrode connected to the power source pad are disposed;
the signal electrode is disposed at an outer periphery of the electrode layer nearer than the ground electrode; and
the ground electrode is disposed at an outer periphery of the electrode layer nearer than the power source electrode.
